(19) United States
(12) Patent Application Publication
(10) Pub. No.: US 2018/0123137 A1
(43) Pub. Date: May 3, 2018

(54) A COMPOSITE MATERIAL OF METAL FOAM-CARBON NANOTUBE, THE PREPARATION METHOD THEREOF AND THE USE THEREOF

(71) Applicant: South China University of Technology, Guangzhou (CN)

(72) Inventors: Jianhuang Zeng, Guangzhou (CN); Muwu LI, Guangzhou (CN)

(21) Appl. No.: 15/560,900

(22) PCT Filed: Dec. 29, 2015
(86) PCT No.: PCT/CN2015/099638

§ 371 Date: Sep. 22, 2017

(30) Foreign Application Priority Data
Apr. 17, 2015 (CN) 201510184553.1

(51) Int. Cl. H01M 4/86; C01B 32/162; H01M 4/96; H01M 4/90; C23C 16/26

(52) U.S. Cl. CPC H01M 4/8657; C01B 32/162; H01M 4/96; B82Y 30/00; H01M 4/9083; C23C 16/26; C01B 2202/22; H01M 4/9041

(57) ABSTRACT

The present invention relates to the technical field of nanometer materials, which discloses a composite material of metal foam-carbon nanotube, the preparation method, and the use thereof. The preparation method of the present invention is: pre-treating a substrate of polyurethane sponge, then placing the pre-treated substrate of polyurethane sponge into a electroless plating solution containing metallic element to carry on a electroless plating reaction, and drying to obtain a metal foam catalyst on the polyurethane sponge substrate; then placing the metal foam catalyst into a tube furnace and raising the temperature to 500˜550° C.; introducing hydrogen and maintaining for 0.5 to 2 hour; then raising the temperature to 600˜800° C. and introducing an acetylenemixture gas as a carbon source, thus the target product is obtained as the carbon nanotubes growing on the surface of the metal foam catalyst by chemical vapor deposition. The prepared carbon nano-fibers or carbon nano-tubes are in situ formed on the transition metal catalyst surface. The metal/carbon interface is firmly bonded; the prepared carbon nano-fibers or carbon nano-tube are with good dispersity and their diameters are controllable and uniform.

### FIELD OF THE INVENTION

The invention belongs to the technical field of nanometer material, and in particular to a composite material of metal foam-carbon nanotube, the corresponding preparation method, and the use thereof.

### BACKGROUND OF THE INVENTION

Carbon black is the most commonly used support for fuel cell electro-catalysts, and it consists of spherical particles with a particle size of 50-100 nm. Because of the small particle size and the zero-dimensional structure, carbon black is easily agglomerated and corroded in the fuel cell operating conditions, thus resulting in decreased catalytic activity. One-dimensional carbon nano-fibers or carbon nano-tubes have a large aspect ratio, which can be adjusted to obtain a large specific surface area and a high degree of graphitization, thus are particularly suitable as fuel cell electro-catalyst support with the anti-agglomerate and corrosion-resistant characteristics. Moreover, the carbon nano-fibers or carbon nano-tubes themselves can act as an oxygen reduction reaction catalyst.

The preparation method of carbon nano-fibers or carbon nano-tubes by means of a transition metal catalyst and chemical vapor deposition is one of the most common preparation methods. Such catalysts are usually prepared by impregnation, thus with a relatively large particle size and are easily agglomerated. A substrate of polyurethane sponge material has a three-dimensional ordered structure and a high porosity (85%˜95%). It can be effectively utilized with the three-dimensional ordered structure, to obtain the uniform catalyst with relatively small particle sizes, by electrolesslyplating a transition metal, thus being a mature way to commercially prepare the metal foam (such as nickel foam, copper foam, etc.). Patent (CN103434207A) discloses a composite material of metal foam-carbon nanotube and its preparation method. However, the composite material is produced by the electroplating of existing carbon nanotubes in the said method, and isnonuniformly distributed. At present, there has been no report on the carbon nano-materials in situ generated on metal foam.

### CONTENTS OF THE INVENTION

In order to solve the above-mentioned shortcomings and problems existed in the prior art, the first object of the present invention is to provide a method for preparing a composite material of metal foam-carbon nanotube.

Another object of the present invention is to provide a composite material of metal foam-carbon nanotube prepared by the above-described method.

A further object of the present invention is to provide the use of the above-mentioned composite material of metal foam-carbon nanotube in fuel cell electro-catalysts or fuel cell electro-catalyst supports.

The object of the present invention is achieved by the following technical solution.

A method for preparing a composite material of metal foam-carbon nanotube comprises the following steps:

(1) Preparation of the metal foam catalyst on a substrate of polyurethane sponge: pre-treating a substrate of polyurethane sponge, then placing the pre-treated substrate of polyurethane sponge into an electroless plating solution containing metallic element to carry on an electroless plating reaction, and drying to obtain a metal foam catalyst on the substrate of polyurethane sponge;

(2) Preparation of composite material of metal foam-carbon nanotube: placing the metal foam catalyst on the substrate of polyurethane sponge in step (1) into a tube furnace and being protected with nitrogen; then raising the temperature of the tube furnace to 500˜550° C. and introducing hydrogen and maintaining 0.5 to 2 hour; then raising the temperature of the tube furnace to 600˜800° C. and introducing a mixture gas of acetylene and nitrogen as a carbon source, the material of carbon nanotubes growing on the surface of the metal foam catalyst by chemical vapor deposition for a deposition time of 2 to 4 hours; then changing the mixture gas of acetylene and nitrogen into nitrogen, naturally cooling to room temperature, and the composite material of metal foam-carbon nanotube is obtained.

The area of the substrate of polyurethane sponge described in step (1) is preferably 5×5 cm².

Said pre-treatment refers to the successive processes of the treatments of chemical degreasing, washing with deionized water, coarsening with potassium permanganate, washing with deionized water, reduction with oxalic acid, washing with deionized water, sensitization and activation with colloidal palladium.

Said chemical degreasing refers to the treatment with a solution containing 15 g/L of NaOH, 15 g/L of Na₃PO₄ and 10 g/L of Na₂CO₃ at 30-35° C. for 3-5 minute. Said coarsening with potassium permanganate refers to the treatment with a solution containing 5-8 g/L of KMnO₄ and 10-15 mL/L of H₂SO₄ at room temperature for 2-3 min. Said reduction with oxalic acid refers to the treatment with a solution containing 15-20 g/L of C₂H₂O₄ at room temperature for 2-3 min. The said sensitization means the treatment with a solution containing 20-30 g/L of SnCl₂ and 30-50 mL/L of HCl at room temperature for 2-3 min. Said activation with colloidal palladium refers to the treatment with a solution containing 0.4-0.6 g/L of PdCl₂, and 30-50 mL/L of HCl at room temperature for 4-5 min.

Said electroless plating solution containing metallic element refers to the nickel-containing electroless plating solution, or a copper-containing electroless plating solution, or a cobalt-containing electroless plating solution.

Said nickel-containing electroless plating solution refers to the electroless plating solution containing 30 g/L of NiSO₄, 10 g/L of NaH₂PO₂, 35 g/L of Na₃Cyt (sodium citrate), and 50 g/L of Na₃PO₄. Said copper-containing electroless plating solution refers to the electroless plating solution containing 10 g/L of CuSO₄, 24 g/L of Na₃Cyt, 3 g/L of NiSO₄, 30 g/L of H₃BO₃, 10 g/L of NaOH and 30 g/L of NaH₂PO₂. Said cobalt-containing electroless plating solution refers to the electroless plating solution containing 28 g/L of CoSO₄, 25 g/L of NaH₂PO₂, 60 g/L of Na₃Cyt and 30 g/L of H₃BO₃.

Said electroless plating reaction refers to the reaction carried out at 45 to 80° C. for 0.5 to 2 hours.

The mass of the metal foam catalyst in the metal foam catalyst on said substrate of polyurethane sponge is 40% to 200% of the mass of the substrate of polyurethane sponge.

Said rising rate of the temperature in step (2) is 10˜15° C./min; and the rate of introducing the mixture gas of acetylene and nitrogen is 50 to 100 mL/min.

Said mixture gas of nitrogen and acetylene is preferably the mixture gas of nitrogen and acetylene in a volume ratio of 1:9.

A composite material of metal foam-carbon nanotube, which is prepared by the above-mentioned method.

The use of the above-mentioned composite material of metal foam-carbon nanotube in fuel cell electro-catalysts or fuel cell electro-catalyst supports.

The preparation principle of the invention is: starting from the substrate of polyurethane sponge; the metal foam catalyst on the substrate of polyurethane sponge is obtained by an electroless plating reaction firstly; and then the composite material of metal foam-carbon nanotube is formed in situ on the surface of the metal foam catalyst by chemical vapor deposition; and at the same time, the substrate of polyurethane sponge is carbonized and the elements after carbonization remained in the composite material.

The preparation method and the product obtained therefrom have the following advantages and good technical effects:

(1) In the present invention, the metal foam catalyst on the substrate of polyurethane sponge is firstly prepared, where the components, structures and loadings of the catalyst can be freely regulated, and in turn, the morphology of the carbon nano-fibers or carbon nanotubes which are subsequently produced can be regulated conveniently.

(2) Different from the impregnation method wherein the catalyst is prepared firstly, then followed by chemical vapor deposition, the carbon nano-fibers or carbon nano-tubes prepared in the present invention are in situ formed on the surface of the transition metal catalyst. The bonding between metal/carbon interface is tight; the prepared carbon nano-fibers or carbon nano-tube are with good dispersity and their diameters are controllable and uniform.

(3) In the present invention, the atoms such as phosphorus and boron introduced in the step of the metal catalyst preparation is deposited by electroless plating, and the nitrogen atoms introduced by the carbonization of the polyurethane sponge itself in the subsequent steps, allow the composite material of the metal foam-carbon nano-tube of the present invention to serve as a cocatalyst when applying in fuel cell electro-catalyst.

### DESCRIPTION OF THE DRAWINGS

FIG. 1 is the scanning electron micrograph of the composite material obtained in Example 1;

FIG. 2 is the XRD diffraction pattern of the composite material obtained in Example 1;

FIG. 3 is the transmission electron micrograph of the composite material obtained in Example 2;

FIG. 4 is the scanning electron micrograph of the composite material obtained in Example 3;

FIG. 5 is the transmission electron micrograph of the composite material obtained in Example 3.

### DESCRIPTION OF EXAMPLE EMBODIMENTS OF THE INVENTION

The present invention will be further described in detail below with reference to examples and figures; however, the embodiments of the present invention are not limited thereto.

### Example 1

A polyurethane sponge (weight of 110 mg) with an area of 5×5 cm² is pre-treated. Which means subjected successively chemical degreasing (NaOH: 15 g/L, Na₃PO₄: 15 g/L, Na₂CO₃: 10 g/L, 35° C., 4 min, washing with deionized water and coarsening with potassium permanganate (KMnO₄: 6 g/L, H₂SO₄: 12 mL/L, at room temperature, 3 min), washing with deionized water and reducing with oxalic acid (C₂H₂O₄: 15 g/L, at room temperature, 2 min), washing with deionized water and sensitizing (SnCl₂: 25 g/L, HCl: 40 mL/L, at room temperature, 3 min), and activating with colloidal palladium (PdCl₂: 0.5 g/L, HCl: 40 mL/L, at room temperature, 4 min). After the pre-treatment, the polyurethane sponge is electrolesslyplated with nickel (NiSO₄: 30 g/L, NaH₂PO₂: 10 g/L, Na₃Cyt: 35 g/L, Na₃PO₄: 50 g/L, 45° C., 1.5 h), so that the surface of the substrate of polyurethane sponge is coated with foam nickel to obtain a foam nickel catalyst on the substrate of polyurethane foam. The product is weighed to be a total mass of 185 mg after drying, of which the foam nickel is 75 mg, accounting for 68% of the mass of the substrate of polyurethane sponge.

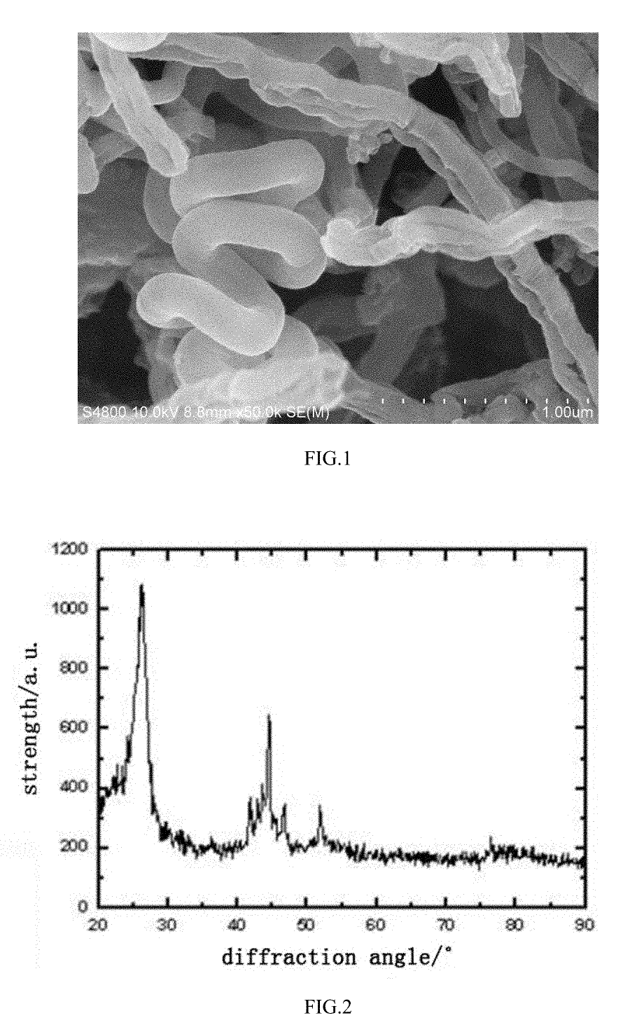

The above-mentioned foam nickel catalyst on the substrate of polyurethane sponge is placed into a tube furnace and protected with nitrogen; then the temperature of the tube furnace is raised from room temperature to 500° C. at a rate of 10° C./min, hydrogen is introduced and kept for 1 hour. The temperature is raised to 700° C. at a rising rate of 15° C./min and a 10% acetylene mixture gas (Nitrogen:acetylene=1:9, in volume ratio) is introduced as a carbon source at a rate of 100 mL/min. The carbon nanotubes are grown on the surface of the metal foam catalyst by chemical vapor deposition for a deposition time of 4 hours. Finally, the metal foam catalyst is naturally cooled to room temperature in the furnace using nitrogen instead of the acetylene mixture gas, and a high yield of composite material of foam nickel-carbon nanotube is obtained. The total mass of the composite material foam nickel-carbon nanotube is 320 mg. The proportion of metallic nickel is 30% as shown by exact thermo-gravimetric analysis. FIG. 1 is the scanning electron microscopy of the obtained composite material. It can be seen from FIG. 1 that the diameters of the carbon nanotube of the composite material are 50˜150 nm. FIG. 2 is the XRD diffraction pattern of the obtained composite material, and the diffraction peak of 25° of graphite and the diffraction peak of 45° of the nickel-phosphorus alloy can be clearly shown in FIG. 2.

### Example 2

The pre-treatment step of the polyurethane sponge in this example is exactly the same as that of Example 1. After the pre-treatment, the polyurethane sponge is electrolesslyplated with copper (CuSO₄: 10 g/L, Na₃Cyt: 24 g/L, NiSO₄: 3 g/L, H₃BO₃: 30 g/L, NaOH: 10 g/L, NaH₂PO₂: 30 g/L, 60° C., 1 h). Thus the surface of the substrate of polyurethane sponge is coated with copper foam to obtain a copper foam catalyst on the substrate of polyurethane sponge. The total mass after drying of the copper foam catalyst is 160 mg, of which the copper foam is 50 mg accounting for 45% of the mass of the substrate of polyurethane sponge.

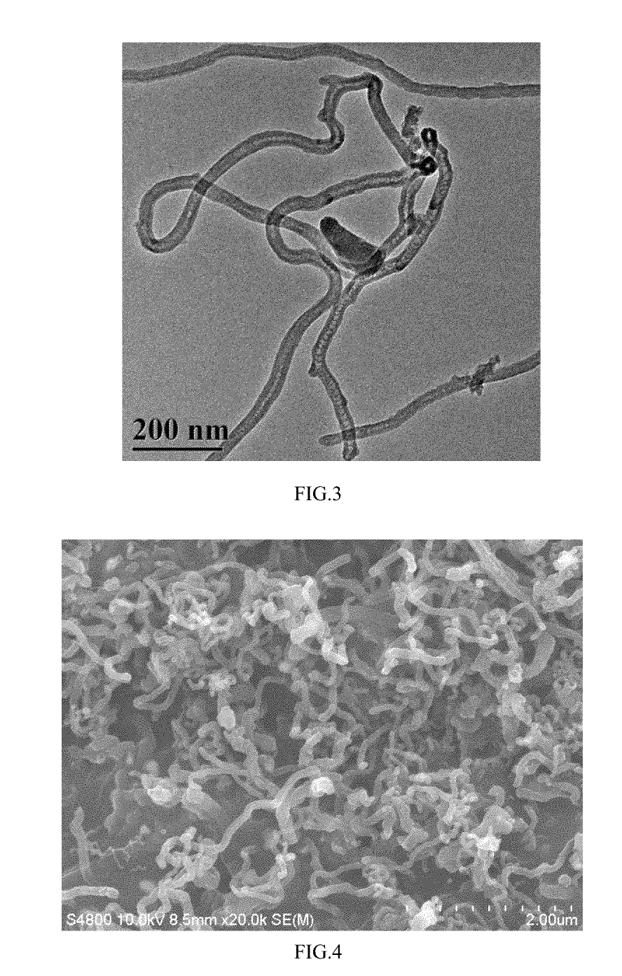

The above-mentioned copper foam catalyst on the substrate of polyurethane sponge is placed into a tube furnace and protected with nitrogen; then the temperature of the tube furnace is raised from room temperature to 550° C. at a rate of 15° C./min, hydrogen is introduced and kept for 1 hour. The temperature is raised to 800° C. at a rising rate of 15° C./min and a 10% acetylene mixture gas (Nitrogen:acetylene=1:9, in volume ratio) is introduced as a carbon source at a rate of 70 mL/min. The carbon nanotubes are grown on the surface of the copper foam catalyst by chemical vapor deposition for a deposition time of 4 hours. Finally, the catalyst is naturally cooled to room temperature in the furnace using nitrogen instead of the acetylene mixture gas, and a composite material copper foam-carbon nanotube is obtained. FIG. 3 is the transmission electron micrograph of the obtained composite material. It can be seen from FIG. 3 that the nanotubes diameters of the composite material are uniform and about 30 nm, with a clear cup-stacked shape.

### Example 3

The pre-treatment step of the polyurethane sponge in this example is exactly the same as that of Example 1. After the pre-treatment, the polyurethane sponge is chemically plated with cobalt (CoSO₄: 28 g/L, NaH₂PO₂: 25 g/L, Na₃Cyt: 60 g/L, H₃BO₃: 30 g/L, 80° C., 0.5 h). Thus the surface of the substrate of polyurethane sponge is coated with cobalt foam, to obtain a cobalt foam catalyst of the substrate of polyurethane sponge.

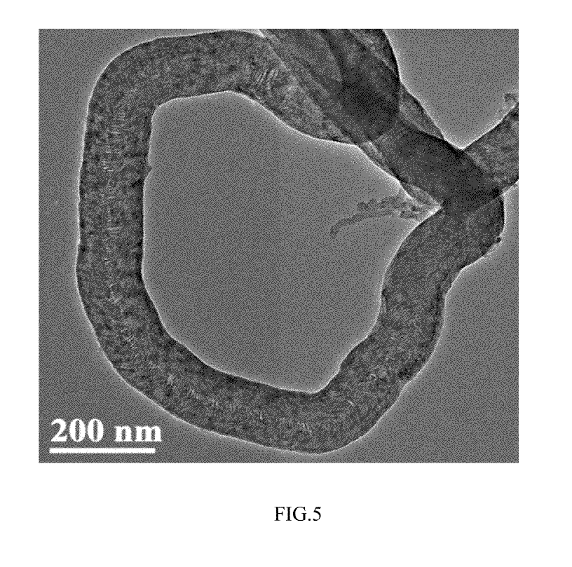

The cobalt foam catalyst on the above-mentioned substrate of polyurethane sponge is placed into a tube furnace and protected by nitrogen; then the temperature of the tube furnace is raised from room temperature to 500° C. at a rate of 12° C./min and hydrogen is introduced for 1 hour. The temperature is raised to 600° C. at a rising rate of 10° C./min and a 10% acetylene mixture (Nitrogen:acetylene=1:9, in volume ratio) is introduced as a carbon source at a rate of 50 mL/min. The carbon nanotubes are grown on the surface of the cobalt foam catalyst by chemical vapor deposition for a deposition time of 2 hours. Finally, the catalyst is naturally cooled to room temperature in the furnace using nitrogen instead of the acetylene mixture gas, and a composite material of the cobalt foam-carbon nanotube is obtained. FIG. 4 and FIG. 5 are the scanning electron microscopies and the transmission electron micrograph of the obtained composite material respectively. It can be seen from the figures that the nanotubes diameters of the composite material are uniform and about 120 nm.

The above examples are preferred embodiments of the present invention; however, the embodiments of the present invention are not limited by the above examples, and any other alteration, modification, substitution, combination and simplification made without departing from the spiritual essence and principle of the present invention are equivalent replacements and fall within the scope of protection of the present invention.

1: A preparation method of a composite material of metal foam-carbon nanotube, characterized in that the preparation method comprises the following preparation steps:
(1) Preparation of a metal foam catalyst on a substrate of polyurethane sponge: pre-treating a substrate of polyurethane sponge, then placing the pre-treated substrate of polyurethane sponge into an electroless plating solution containing metallic element to carry out an electroless plating reaction, and drying to obtain a metal foam catalyst on the substrate of polyurethane sponge;
(2) Preparation of composite material of metal foam-carbon nanotube: placing the metal foam catalyst on the substrate of polyurethane sponge mentioned in step (1) into a tube furnace and being protected with nitrogen; then raising the temperature of the tube furnace to 500˜550° C. and introducing hydrogen and maintaining 0.5 to 2 hour; then raising the temperature of the tube furnace to 600˜800° C. and introducing a mixture gas of acetylene and nitrogen as a carbon source, the material of carbon nanotubes growing on the surface of the metal foam catalyst by chemical vapor deposition for a deposition time of 2 to 4 hours; then changing the mixture gas of acetylene and nitrogen into nitrogen, naturally cooling the metal foam catalyst to room temperature; and the composite material of metal foam-carbon nanotube is obtained.

2: A preparation method of a composite material of metal foam-carbon nanotube according to claim 1, wherein the area of the substrate of polyurethane sponge described in step (1) is 5×5 cm²; and the said pre-treatment refers to the subsequent processes of treatments of chemical degreasing, deionized water-washing, potassium permanganate-coarsening, deionized water-washing, oxalic acid-reduction, deionized water-washing, sensitization and colloidal palladium-activation.

3: A preparation method of a composite material of metal foam-carbon nanotube according to claim 2, characterized in that said chemical degreasing refers to the treatment with a solution containing 15 g/L of NaOH, 15 g/L of Na₃PO₄ and 10 g/L of Na₂CO₃ at a temperature of 30-35° C. for 3-5 minute, said potassium permanganate-coarsening refers to the treatment with a solution containing 5-8 g/L of KMnO₄ and 10-15 mL/L of H₂SO₄ at room temperature for 2-3 min; said oxalic acid-reduction refers to the treatment with a solution containing 15-20 g/L of C₂H₂O₄ at room temperature for 2-3 min; said sensitization refers to the treatment with a solution containing 20-30 g/L of SnCl₂ and 30-50 mL/L of HCl at room temperature for 2-3 min; said colloidal palladium-activation refers to the treatment with a solution containing 0.4-0.6 g/L of PdCl₂, and 30-50 mL/L of HCl at room temperature for 4-5 min.

4: A preparation method of a composite material of metal foam-carbon nanotube according to claim 1, characterized in that said electroless plating solution containing metallic element refers to a nickel-containing electroless plating solution, a copper-containing electroless plating solution or a cobalt-containing electroless plating solution.

5: A preparation method of a composite material of metal foam-carbon nanotube according to claim 4, characterized in that said nickel-containing electroless plating solution refers to an electroless plating solution containing 30 g/L of NiSO₄, 10 g/L of NaH₂PO₂, 35 g/L of Na₃Cyt, and 50 g/L of Na₃PO₄; said copper-containing electroless plating solution refers to an electroless plating solution containing 10 g/L of CuSO₄, 24 g/L of Na₃Cyt, 3 g/L of NiSO₄, 30 g/L of H₃BO₃, 10 g/L of NaOH and 30 g/L of NaH₂PO₂; said cobalt-containing electroless plating solution refers to an electroless plating solution containing 28 g/L of CoSO₄, 25 g/L of NaH₂PO₂, 60 g/L of Na₃Cyt and 30 g/L of H₃BO₃.

6: A preparation method of a composite material of metal foam-carbon nanotube according to claim 1, characterized in that said electroless plating reaction refers to the reaction being carried out at 45 to 80° C. for 0.5 to 2 hours; the mass of the metal foam catalyst produced by the electroless plating reaction is 40% to 200% of the mass of the substrate of polyurethane sponge.

7: A preparation method of a composite material of metal foam-carbon nanotube according to claim 1, characterized in that said raising temperature rate in step (2) is 10˜15° C./min; and the rate of introducing the mixture gas of acetylene and nitrogen is 50 to 100 mL/min.

8: A preparation method of a composite material of metal foam-carbon nanotube according to claim 1, characterized in that said mixture gas of acetylene and nitrogen is the mixture of nitrogen and acetylene in a volume ratio of 1:9.

9: A composite material of metal foam-carbon nanotube, prepared by the method according to claim 1.

10: The composite material of metal foam-carbon nanotube according to claim 9 for a fuel cell electro-catalysts or fuel cell electro-catalyst supports.
